(19) United States
(12) Patent Application Publication
(10) Pub. No.: US 2010/0138717 A1
(43) Pub. Date: Jun. 3, 2010

(54) FORK CODES FOR ERASURE CODING OF DATA BLOCKS

(75) Inventors: Yunnan Wu, Redmond, WA (US); Georgios-Alex Dimakis, Los Angeles, CA (US)

Correspondence Address: MICROSOFT CORPORATION, ONE MICROSOFT WAY, REDMOND, WA, 98052, US

(73) Assignee: MICROSOFT CORPORATION, Redmond, WA (US)

(21) Appl. No.: 12/326,880

(22) Filed: Dec. 2, 2008

(51) Int. Cl. H03M 13/05; G06F 11/07

(52) U.S. Cl. 714/752; 714/E11.021

(57) ABSTRACT

Described is a technology in which data blocks are coded into erasure coded blocks in a two-stage, two-level processing operation. In a first processing stage, such as via MDS coding, original blocks are coded into a first level of output data blocks including one or more parity blocks. In a second, fork code processing stage, the first level blocks are partitioned into groups, and those groups used to generate a second level of parity blocks. The blocks are maintained among a plurality of storage nodes. Recovery of a failed data block is accomplished by accessing only the other data blocks associated with the failed data block's coding group (whenever possible), thus facilitating significantly more efficient recovery than with conventional erasure coding techniques.

### BACKGROUND

Erasure coding, such as MDS (Maximum-Distance Separable) erasure coding, is a known technique that is used to improve the reliability of data communication and data storage systems. In general, erasure coding allows lost data to be recovered in a manner that provides redundancy without needing to exactly replicate each piece of data. Classical erasure coding theory focuses on the tradeoff between redundancy and error tolerance.

Known erasure coding techniques are not always adequate to use in modern storage systems and computing environments. In particular, when recovering lost data, other metrics need to be considered with respect to whether a recovery mechanism meets the needs of its users. For example, when erasure-coded backup data is accessible over a network, network traffic may make recovery very inefficient. Similarly, disk input and output (I/O) that is incurred when recovering from failures may be a very large factor in recovery time.

### SUMMARY

This Summary is provided to introduce a selection of representative concepts in a simplified form that are further described below in the Detailed Description. This Summary is not intended to identify key features or essential features of the claimed subject matter, nor is it intended to be used in any way that would limit the scope of the claimed subject matter.

Briefly, various aspects of the subject matter described herein are directed towards a technology by which data blocks are coded into erasure coded blocks in a two-stage, two-level processing operation. In a first processing stage, such as via MDS coding, original blocks are coded into a first level of coded blocks. The first level may be generated via a systematic code, in which case the output coded blocks include the original blocks and one or more parity blocks (i.e., blocks that are functions of the original blocks); alternatively, the first level may be generated via a non-systematic code. In the second processing stage of fork codes, the first level blocks are partitioned into groups, and those groups used to generate a second level of parity blocks. The first level coded blocks in each group, together with the second-level parity blocks generated from them, are said to form a coding group. The blocks are maintained among a plurality of storage nodes.

In one aspect, recovery of a failed data block (corresponding to its node) is accomplished by determining whether the other data blocks associated with the failed data block's coding group are sufficient to perform the recovery. If so, only those data blocks need to be accessed to perform the recovery. In this manner, recovery is often significantly more efficient since fewer blocks need to be accessed to perform the recovery than with conventional erasure coding techniques.

Other advantages may become apparent from the following detailed description when taken in conjunction with the drawings.

### BRIEF DESCRIPTION OF THE DRAWINGS

The present invention is illustrated by way of example and not limited in the accompanying figures in which like reference numerals indicate similar elements and in which:

FIG. 1 is a block diagram showing example components for erasure coding input data blocks into coded output data blocks, including fork-coded blocks from groups of the coded blocks.

FIG. 2 is a representation of fork-coded output blocks including blocks coded in a first coding stage and groups of blocks coded in a second, fork-coding stage.

FIG. 3 is a flow diagram representing example steps for coding data blocks in a first coding stage and groups of blocks coded in a second, fork-coding stage.

FIG. 4 is a flow diagram representing example steps for recovering one or more data blocks by accessing data blocks maintained from fork coding.

FIG. 5 shows an illustrative example of a computing environment into which various aspects of the present invention may be incorporated.

### DETAILED DESCRIPTION

Various aspects of the technology described herein are generally directed towards a class of erasure codes, referred to herein as fork codes, which may be used in data recovery of blocks of data, (wherein as used herein, a “block” is any amount of data, e.g., a file, a volume, a unit of storage, or any fixed amount such as three kilobytes, two megabytes, four gigabytes, and so forth). In general, with fork-based erasure coding, the recovery time is ordinarily much faster than with traditional erasure coding, at the tradeoff of some additional storage. As will be understood, a fork code achieves a good tradeoff of several performance metrics that are important to a storage system, including between redundancy, erasure tolerance, and/or recovery complexity.

It should be understood that any of the examples described herein are non-limiting examples. As such, the present invention is not limited to any particular embodiments, aspects, concepts, structures, functionalities or examples described herein. Rather, any of the embodiments, aspects, concepts, structures, functionalities or examples described herein are non-limiting, and the present invention may be used in various ways that provide benefits and advantages in computing and data storage and/or recovery in general.

By way of background erasure coding, consider two original information blocks, A and B. A straightforward way to store information to recover these blocks is to replicate them among storage nodes, e.g., as two copies of the two original blocks, A and B, at four nodes. If any single node fails, at least one copy remains; however if two nodes fail, it may be that both are B nodes, for example, whereby no copy of B can be recovered. Note that a storage node, or simply “node” as used herein, may be any storage device or part thereof, and nodes are typically arranged such that each is independent of the others with respect to failing.

Erasure coding is a more advanced way of adding redundancy, as in the previous example, erasure coding allows recovery without data loss even if any two nodes fail (unlike a replication situation where both nodes containing B blocks fail). This is accomplished, for example, by storing a copy of each block along with mathematical combinations of the data from each block, e.g., by storing block A at node 1, block B at node 2, a parity block of A+B at node 3, and a parity block of A+2B at node 4, where the addition and multiplication operations are performed in a finite field. This erasure coded system can tolerate any two node failures without data loss, e.g., if the first and fourth nodes fail, the system can recover A and B from B and A+B; this can be done by computing (A+B)−B=A. Erasure coding thus provides redundancy/better node failure tolerance in an efficient way.

In erasure coding in general, a number of information blocks (typically denoted by k) are encoded into a number of coded blocks (typically denoted by n) by a linear transformation defined in a finite field. An erasure code can be specified by an n×k generator matrix G, which describes how each coded block is formed as a linear combination of the original information blocks. In the above example, of A, B, A+B and A+2B, the generator matrix is:

$$G = [ \begin{matrix}1 & 0 \\ 0 & 1 \\ 1 & 1 \\ 1 & 2\end{matrix} ] .$$

with the four rows in G corresponding to these four coded blocks, respectively. An (n,k) erasure code is said to be systematic if the first k coded blocks are the original k information blocks; the above code is thus a systematic code. Note that in erasure decoding, the original information blocks are recovered by applying another linear transformation to the available data blocks; erasure decoding essentially amounts to solving linear equations.

Classical erasure coding theory focuses on the tradeoff between redundancy and error tolerance. Under this criterion, as is known, an MDS (Maximum-Distance Separable) erasure code is optimal, where an (n,k) MDS code encodes k information blocks into n coded blocks (of same length as the original blocks) such that any k coded blocks can be used to reconstruct the original k information blocks. For example, a systematic (7, 5) MDS code has five output blocks representing the five original information blocks, namely A, B, C, D and E, plus two blocks for the additional two parity coded blocks, which are functions of the five original information blocks, namely A+B+C+D+E, and A+2B+3C+4D+5E in one systematic (7, 5) MDS code example.

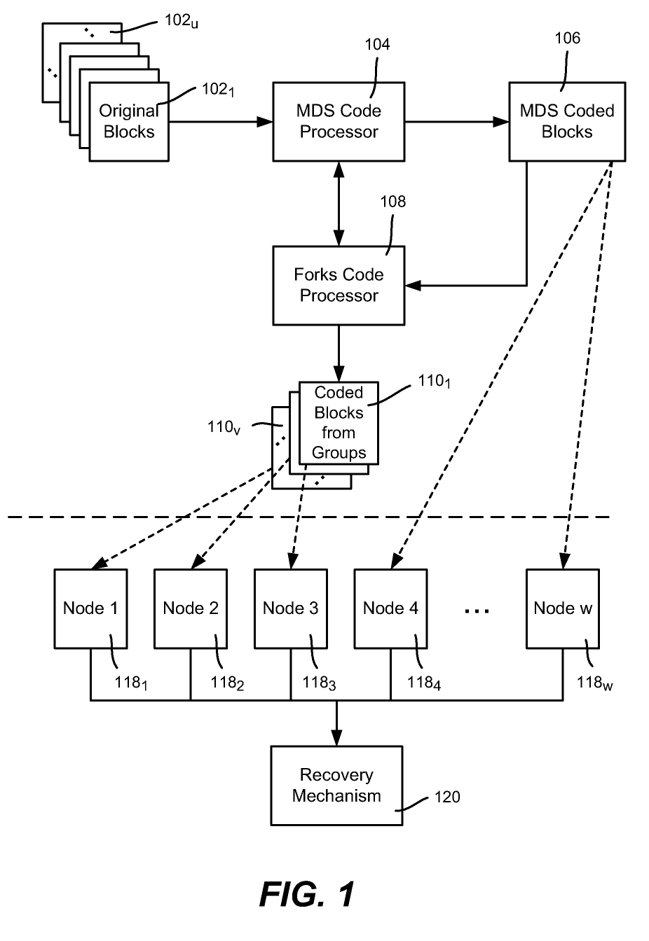

FIG. 1 shows various aspects related to fork code coding, in which a two-stage encoding process is performed that provides various benefits described below. In general, given a set of original data blocks 102₁-102ᵤ, the coding structure of the fork code includes a first-stage, such as performed by an MDS code processor 104 or the like, and outputs an MDS-coded output blocks 106 at a first level. Note that MDS is only one suitable encoding mechanism. Note that copies of the original blocks 102₁-102ᵤ may be part of the coded blocks 106, that is, the fork-based erasure code may be systematic.

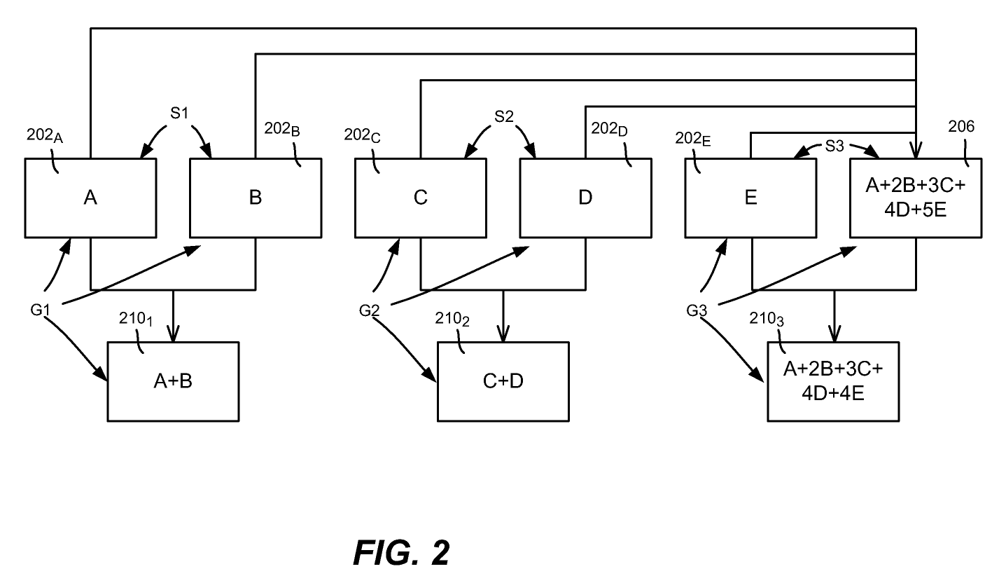

In the second stage, the coded blocks 106 output by the first stage are partitioned into multiple disjoint sets, shown in FIG. 1 as coded blocks 110₁-110ᵥ. Second-level parity blocks 110₁-110ᵥ are coded from these disjoint groups (e.g., S1-S3 in FIG. 2). The first level coded blocks in each group, together with the second-level parity blocks generated from them, are said to form a coding group. For example, in FIG. 2, the coding groups are denoted by G1-G3.

Also shown for completeness in FIG. 1 is storage and recovery, below the dashed line. In general, the coded blocks 106 and the coded blocks 110₁-110ᵥ generated from the coding groups are stored among nodes 118¹-118_{w} one block per node. In the event of a block failure, (or a multiple block failure as described below), a recovery mechanism 120 can access the appropriate nodes and re-compute the failed block's data from the coded blocks. Note that for efficiency, in one implementation described below, the recovery mechanism 120 recovers from a failure by accessing only the other nodes that are involved in the same coding group, when possible.

FIG. 2 illustrates a Fork code with the two-stage structure, in which the arrows indicate that a set of five original blocks 202_{A}-202_{E} are linearly combined to form the last coded block 206, as well as combined into coded blocks 210₁ and 210₂ for the coding groups G1-G3. Note that the first level parity block 206 is also combined with block 202_{E}, to form the second level parity block 210₃. Further note that the term “fork” code is obtained from this second stage linear combination, which resembles a number of two-pronged forks.

Thus, in the example of FIG. 2, five (k=5) original information blocks are encoded into nine (n=9) coded blocks. As the five original information blocks are part of the blocks, this code is a systematic code. The first stage is a (6,5) MDS code, which produces the six coded blocks 202_{A}-202_{E} and 206. The second stage of coding partitions the six coded blocks output by the first stage (blocks 202_{A}-202_{E} and 206) into three disjoint groups S1-S3, namely (202_{A}, 202_{B}), (202_{C}, 202_{D}) and (202_{E}, 206), respectively. For each group, a coded block is generated as a linear combination of the blocks in that coding group, providing the blocks 210₁-210₃. Thus three coding groups are formed, namely (202_{A}, 202_{B}, 210₁), (202_{C}, 202_{D}, 210₂) and (202_{E}, 206, 210₃), respectively.

The benefits of a fork code can be seen from its properties. Recovering from a single failure is simple, because each node can be recovered from the other nodes in the same coding group. For example, in FIG. 2, an original copy of block A can be recovered from the block 202_{B} and the coded block 210₁ (A+B) for the group, because A, B and A+B form a coding group in the second stage. Only two nodes and their respective blocks are involved in the recovery. In contrast, conventional MDS (6,5) erasure coding (e.g., A, B, C, D, E, and A+B+C+D+E) requires accessing five nodes to recover a single failed block, which for example correlates to five gigabytes of data I/O and data transfer to recover a single one gigabyte block.

Thus, one purpose of the fork in the second stage is to enable fast recovery from single failures (or multiple isolated failures where each fork coding group has only a single failure). In general, a recovery system recovers from a failure by only accessing other nodes involved in the same coding group, when possible.

Another property is that with proper configuration parameters, the fork code can achieve a good tradeoff of overall erasure protection capability and fast recovery from single failures. For instance, in FIG. 2, the fork code can tolerate any two node failures without data loss. If the two node failures are not nodes that are in the same coding group with one another, the recovery is very efficient as for each failed node, only the coding group's non-failed node(s) and parity node need to be accessed for recovery. If the two nodes that fail are in the same coding group, more nodes including those outside the coding group need to be accessed during recovery, but recovery is still possible; (note that such failures are relatively rare, and in any event, such a recovery is similar to conventional MDS erasure coding recovery). Still further, the fork code technology can tolerate some other failure patterns with three or more failures, whereas a conventional MDS erasure code may not be able to do so. In sum, an MDS structure in the second stage, coupled with the fork code, thus offers good overall erasure protection while providing efficient recovery.

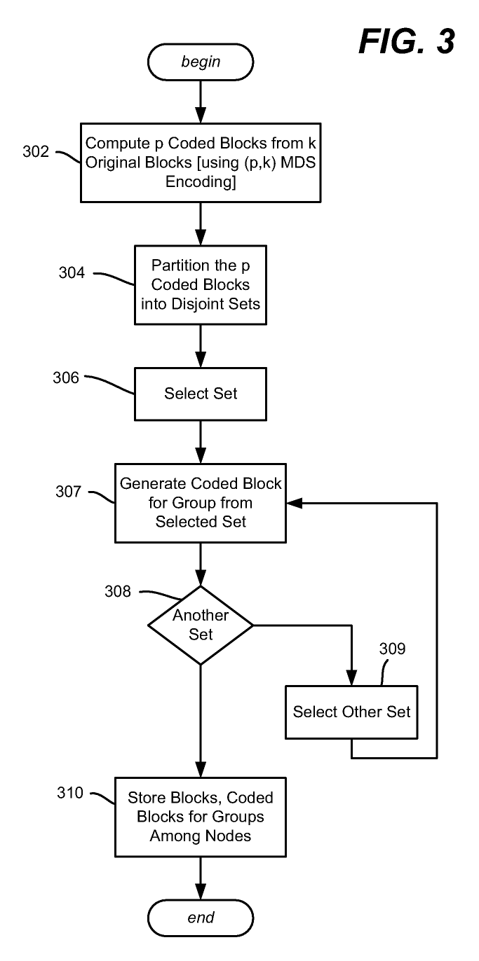

It should be noted that the example of FIG. 2 is only one such example for five input data blocks, MDS (6,5) first stage coding and second stage coding having two blocks in each coding group. A more general explanation of the two-stage fork code is set forth in FIG. 3. In the first stage represented by step 302, p coded blocks are computed from k original data blocks such that the first stage is a (p,k) MDS code. Such a (p,k) MDS code can be systematic (in which case the p coded blocks include k original blocks plus p-k parity blocks) or nonsystematic.

In the second stage, additional coded blocks are computed from the p coded blocks. More particularly, as represented by step 304, the p blocks output by the first stage are partitioned into multiple disjoint sets.

Via steps 306-309, for each such disjoint set, e.g., S={X₁, . . . , Xⱼ}, one or more additional coded blocks, e.g., Y₁, . . . Y_{L}, are generated as a function of the blocks in the set S. In one implementation, Y₁, . . . , Y_{L} are such that X₁, . . . , X_{J,} Y₁, . . . Y_{L} form an MDS code. Following the grouping and the coding of the groups, the coded blocks and coded blocks for the groups are stored among the nodes.

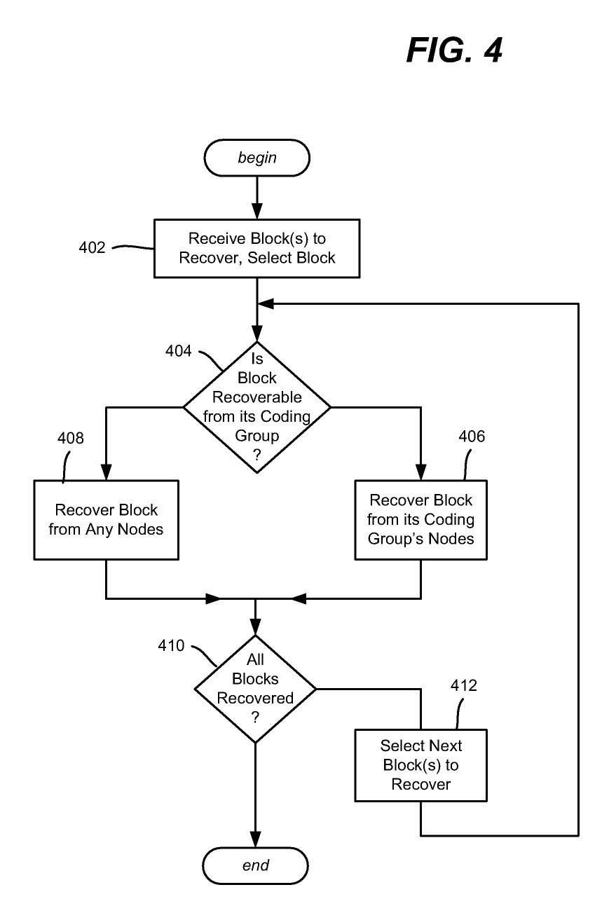

FIG. 4 summarizes recovery operations, beginning at step 402 where a recovery mechanism receives instructions to recover one or more blocks, corresponding to one or more nodes. As described above, at step 404 the recovery mechanism includes logic that first attempts to recover a block from the blocks within its coding group, which is known to (or discoverable by) the recovery mechanism. If possible, (e.g., the non-failed nodes corresponding to the group has sufficient blocks to perform the recovery), step 404 branches to step 406 to perform the recovery. If not, step 408 is instead performed to access as many nodes as needed to perform the recovery. Note that FIG. 4 is simplified, including that recovery errors are not shown, such as situations in which recovery is not possible because too many nodes have failed. Steps 410 and 412 repeat the process for any other blocks that need to be recovered.

### Exemplary Operating Environment

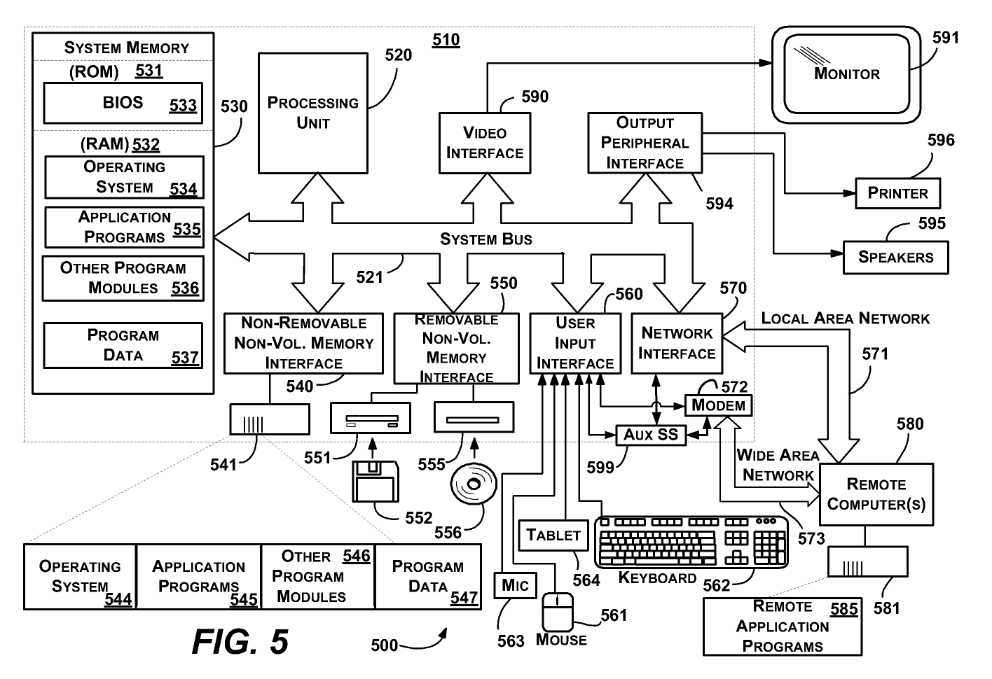

FIG. 5 illustrates an example of a suitable computing and networking environment 500 on which the examples of FIGS. 1-4 may be implemented. The computing system environment 500 is only one example of a suitable computing environment and is not intended to suggest any limitation as to the scope of use or functionality of the invention. Neither should the computing environment 500 be interpreted as having any dependency or requirement relating to any one or combination of components illustrated in the exemplary operating environment 500.

The invention is operational with numerous other general purpose or special purpose computing system environments or configurations. Examples of well known computing systems, environments, and/or configurations that may be suitable for use with the invention include, but are not limited to: personal computers, server computers, hand-held or laptop devices, tablet devices, multiprocessor systems, microprocessor-based systems, set top boxes, programmable consumer electronics, network PCs, minicomputers, mainframe computers, distributed computing environments that include any of the above systems or devices, and the like.

The invention may be described in the general context of computer-executable instructions, such as program modules, being executed by a computer. Generally, program modules include routines, programs, objects, components, data structures, and so forth, which perform particular tasks or implement particular abstract data types. The invention may also be practiced in distributed computing environments where tasks are performed by remote processing devices that are linked through a communications network. In a distributed computing environment, program modules may be located in local and/or remote computer storage media including memory storage devices.

With reference to FIG. 5, an exemplary system for implementing various aspects of the invention may include a general purpose computing device in the form of a computer 510. Components of the computer 510 may include, but are not limited to, a processing unit 520, a system memory 530, and a system bus 521 that couples various system components including the system memory to the processing unit 520. The system bus 521 may be any of several types of bus structures including a memory bus or memory controller, a peripheral bus, and a local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus also known as Mezzanine bus.

The computer 510 typically includes a variety of computer-readable media. Computer-readable media can be any available media that can be accessed by the computer 510 and includes both volatile and nonvolatile media, and removable and non-removable media. By way of example, and not limitation, computer-readable media may comprise computer storage media and communication media. Computer storage media includes volatile and nonvolatile, removable and non-removable media implemented in any method or technology for storage of information such as computer-readable instructions, data structures, program modules or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can accessed by the computer 510. Communication media typically embodies computer-readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of the any of the above may also be included within the scope of computer-readable media.

The system memory 530 includes computer storage media in the form of volatile and/or nonvolatile memory such as read only memory (ROM) 531 and random access memory (RAM) 532. A basic input/output system 533 (BIOS), containing the basic routines that help to transfer information between elements within computer 510, such as during start-up, is typically stored in ROM 531. RAM 532 typically contains data and/or program modules that are immediately accessible to and/or presently being operated on by processing unit 520. By way of example, and not limitation, FIG. 5 illustrates operating system 534, application programs 535, other program modules 536 and program data 537.

The computer 510 may also include other removable/non-removable, volatile/nonvolatile computer storage media. By way of example only, FIG. 5 illustrates a hard disk drive 541 that reads from or writes to non-removable, nonvolatile magnetic media, a magnetic disk drive 551 that reads from or writes to a removable, nonvolatile magnetic disk 552, and an optical disk drive 555 that reads from or writes to a removable, nonvolatile optical disk 556 such as a CD ROM or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM, and the like. The hard disk drive 541 is typically connected to the system bus 521 through a non-removable memory interface such as interface 540, and magnetic disk drive 551 and optical disk drive 555 are typically connected to the system bus 521 by a removable memory interface, such as interface 550.

The drives and their associated computer storage media, described above and illustrated in FIG. 5, provide storage of computer-readable instructions, data structures, program modules and other data for the computer 510. In FIG. 5, for example, hard disk drive 541 is illustrated as storing operating system 544, application programs 545, other program modules 546 and program data 547. Note that these components can either be the same as or different from operating system 534, application programs 535, other program modules 536, and program data 537. Operating system 544, application programs 545, other program modules 546, and program data 547 are given different numbers herein to illustrate that, at a minimum, they are different copies. A user may enter commands and information into the computer 510 through input devices such as a tablet, or electronic digitizer, 564, a microphone 563, a keyboard 562 and pointing device 561, commonly referred to as mouse, trackball or touch pad. Other input devices not shown in FIG. 5 may include a joystick, game pad, satellite dish, scanner, or the like. These and other input devices are often connected to the processing unit 520 through a user input interface 560 that is coupled to the system bus, but may be connected by other interface and bus structures, such as a parallel port, game port or a universal serial bus (USB). A monitor 591 or other type of display device is also connected to the system bus 521 via an interface, such as a video interface 590. The monitor 591 may also be integrated with a touch-screen panel or the like. Note that the monitor and/or touch screen panel can be physically coupled to a housing in which the computing device 510 is incorporated, such as in a tablet-type personal computer. In addition, computers such as the computing device 510 may also include other peripheral output devices such as speakers 595 and printer 596, which may be connected through an output peripheral interface 594 or the like.

The computer 510 may operate in a networked environment using logical connections to one or more remote computers, such as a remote computer 580. The remote computer 580 may be a personal computer, a server, a router, a network PC, a peer device or other common network node, and typically includes many or all of the elements described above relative to the computer 510, although only a memory storage device 581 has been illustrated in FIG. 5. The logical connections depicted in FIG. 5 include one or more local area networks (LAN) 571 and one or more wide area networks (WAN) 573, but may also include other networks. Such networking environments are commonplace in offices, enterprise-wide computer networks, intranets and the Internet.

When used in a LAN networking environment, the computer 510 is connected to the LAN 571 through a network interface or adapter 570. When used in a WAN networking environment, the computer 510 typically includes a modem 572 or other means for establishing communications over the WAN 573, such as the Internet. The modem 572, which may be internal or external, may be connected to the system bus 521 via the user input interface 560 or other appropriate mechanism. A wireless networking component 574 such as comprising an interface and antenna may be coupled through a suitable device such as an access point or peer computer to a WAN or LAN. In a networked environment, program modules depicted relative to the computer 510, or portions thereof, may be stored in the remote memory storage device. By way of example, and not limitation, FIG. 5 illustrates remote application programs 585 as residing on memory device 581. It may be appreciated that the network connections shown are exemplary and other means of establishing a communications link between the computers may be used.

An auxiliary subsystem 599 (e.g., for auxiliary display of content) may be connected via the user interface 560 to allow data such as program content, system status and event notifications to be provided to the user, even if the main portions of the computer system are in a low power state. The auxiliary subsystem 599 may be connected to the modem 572 and/or network interface 570 to allow communication between these systems while the main processing unit 520 is in a low power state.

### CONCLUSION

While the invention is susceptible to various modifications and alternative constructions, certain illustrated embodiments thereof are shown in the drawings and have been described above in detail. It should be understood, however, that there is no intention to limit the invention to the specific forms disclosed, but on the contrary, the intention is to cover all modifications, alternative constructions, and equivalents falling within the spirit and scope of the invention.

What is claimed is:

1. In a computing environment, a method comprising, coding original data blocks into a first set of output data blocks including at least one parity data block, partitioning the output data blocks into one or more groups, and coding the groups into a second set of output data blocks.

2. The method of claim 1 further comprising, maintaining the first set of output data blocks and the second set of output data blocks among a plurality of nodes.

3. The method of claim 2 wherein the blocks within a group and the data blocks computed therefrom comprise a coding group, and further comprising, determining whether a data block that needs to be recovered can be recovered using only other data blocks associated with that data block's coding group, and if so, recovering the data block that needs to be recovered by using the other data blocks associated with that data block's coding group.

4. The method of claim 3 wherein the data block that needs to be recovered cannot be recovered using only other data blocks associated with that data block's coding group, and further comprising, accessing at least one block that is not within that data block's coding group to perform a recovery operation.

5. The method of claim 1 wherein coding the original data blocks into the first set of output data blocks comprises performing MDS erasure coding to generate the at least one parity data block.

6. The method of claim 1 wherein coding the groups comprises performing MDS erasure coding to generate the second set of output data blocks.

7. In a computing environment, a system comprising, a first stage coding processor that generates a first set of output data blocks from original data blocks, the output data blocks including at least one data block that is generated as a function of the original data blocks, and a second stage coding processor that partitions the first set of output data blocks into groups and generates a second set of output data blocks, including data blocks that are functions of the data blocks from the groups.

8. The system of claim 7 wherein the first stage coding processor generates the first set of output data blocks via MDS coding.

9. The system of claim 7 wherein first second coding processor generates the second set of output data blocks via MDS coding.

10. The system of claim 7 wherein the system includes storage nodes for maintaining the first set of output data blocks and the second set of output data blocks.

11. The system of claim 10 further comprising, a recovery mechanism that accesses the storage nodes to recover a copy of at least one data block.

12. The system of claim 11 wherein the blocks within a group and the data blocks computed therefrom comprise a coding group, and wherein the recovery mechanism includes logic that recovers a data block by using only other data blocks associated with that data block's coding group when those other data blocks are sufficient to recover that data block.

13. The system of claim 12 wherein the logic recovers the data block by using at least one other data block that is not associated with that data block's coding group when the other data blocks associated with that data block's coding group are not sufficient for recovery.

14. The system of claim 10 wherein the second set of output data blocks includes a parity block that is generated from at least one parity block in the first set of output data blocks.

15. One or more computer-readable media having computer-executable instructions, which when executed perform steps, comprising:
generating a first level of output data blocks (including one or more parity blocks) from original blocks;
partitioning the original blocks and at least one parity block from the first level into groups;
generating a second level of parity blocks from the groups, including generating at least one second level parity block from a first level parity block; and
maintaining the first level of output data blocks, and the second level of parity blocks among a plurality of nodes.

16. The one or more computer-readable media of claim 15 having further computer-executable instructions, comprising recovering a recovered data block by accessing at least two of the nodes.

17. The one or more computer-readable media of claim 16 wherein the blocks within a group and the data blocks computed therefrom comprise a coding group, and wherein recovering the recovered data block comprises accessing only other data blocks associated with that data block's coding group to perform the recovery.

18. The one or more computer-readable media of claim 16 wherein the blocks within a group and the data blocks computed therefrom comprise a coding group, and wherein recovering the recovered data block comprises determining that one or more data blocks not associated with that data block's coding group are needed to perform the recovery.

19. The one or more computer-readable media of claim 16 wherein generating the first level of one or more parity blocks from the original blocks comprises performing MDS erasure coding.

20. The one or more computer-readable media of claim 16 wherein generating the second level of parity blocks comprises performing MDS erasure coding.
